(19) United States
(12) Patent Application Publication
(10) Pub. No.: US 2008/0068868 A1
(43) Pub. Date: Mar. 20, 2008

(54) Power MESFET Rectifier

(75) Inventor: Richard K. Williams, Cupertino, CA (US)

Correspondence Address: ADVANCED ANALOGIC TECHNOLOGIES, 830 EAST ARQUES AVE, SUNNYVALE, CA, 94085, US

(73) Assignee: ADVANCED ANALOGIC TECHNOLOGIES, INC., Sunnyvale, CA (US)

(21) Appl. No.: 11/307,203

(22) Filed: Jan. 26, 2006

Related U.S. Application Data
(60) Provisional application No. 60/597,412, filed on Nov. 29, 2005.

(51) Int. Cl. H02M 3/335; H01L 27/06; H01L 29/20

(52) U.S. Cl. 363/21.06; 257/268; 257/E29.317; 257/E27.016; 257/E29.089

(57) ABSTRACT

A rectifier MESFET includes an N-channel MESFET having its gate connected to its source, and at the same current density having a voltage drop lower than the gate Schottky diode. A Schottky diode may be connected in parallel with the N-channel device to provide over current protection. A Zener may also be connected in parallel to provide reverse voltage protection. A second N-channel device may be connected in parallel. The addition of the second N-channel provides two different operational mode: synchronous rectification where the majority of current flows through the low resistance first N-channel device and asynchronous rectification where the majority of current flows through the somewhat higher resistance first N-channel device.

### RELATED APPLICATIONS

This application is one of a group of concurrently filed applications that include related subject matter. The six titles in the group are: 1) High Frequency Power MESFET Gate Drive Circuits, 2) High-Frequency Power MESFET Boost Switching Power Supply, 3) Rugged MESFET for Power Applications, 4) Merged and Isolated Power MESFET Devices, 5) High-Frequency Power MESFET Buck Switching Power Supply, and 6) Power MESFET Rectifier. Each of these documents incorporates all of the others by reference.

### BACKGROUND OF INVENTION

Rectification is a common function in all modern power electronic circuitry. Rectification performs the simple function of AC-to-DC conversion in offline power supplies as well as in DC-to-DC switching power supplies. Today, rectification is performed using P-N junction rectifiers, Schottky rectifiers, or power MOSFETs (operating as a synchronous rectifiers), each of which suffers from certain limitations, especially in high frequency DC/DC conversion applications and circuits.

Two-Terminal Rectifiers

Silicon P-N junction rectifiers as shown in FIG. 1A and represented schematically in FIG. 1B are commonly used as rectifiers at low frequencies. As illustrated in FIG. 1C, such junction rectifiers are capable of high off-state blocking voltages, typically from 7 volts to over 1000 volts with minimal leakage current (curve 4) but suffer from a high forward drop V_{F} during conduction (curve 3), roughly 0.7V to 1.0V. The forward drop tends to increase for higher blocking voltages due to series resistance but remains above 0.7V even for low voltage silicon PN diodes. With such a high on-state drop, the power loss in P-N rectifiers operating at high current conditions is too high for use in most applications other than in very high-voltage high-power circuits where excess power may be removed using large heat sinks. In lower voltage applications and especially in battery powered applications, the relatively large voltage drop in P-N junction rectifiers results in low conversion efficiency, making them unattractive even in low current applications.

Silicon P-N junction diodes also suffer from excess stored charge adversely affecting the diode's switching performance and efficiency. This excess charge, specifically minority carriers, must be depleted before the diode can stop conduction. In switch-mode voltage regulation, the excess charge can result in current momentarily flowing in the reverse direction through the rectifier, causing undesirable switching power losses (called reverse recovery losses), lowering efficiency, and producing unwanted electrical noise. The stored charge of silicon P-N junction diodes essentially limits the maximum switching frequency in which such diodes can be used, typically in the sub-Megahertz range.

Metal-semiconductor rectifiers Schottky rectifiers as shown in FIG. 1D and represented schematically as FIG. 1E are more beneficial than P-N junction rectifiers in low voltage higher-frequency applications. The metal-semiconductor interface stores very little charge during conduction thereby minimizing, but not totally eliminating, reverse recovery losses. The Schottky rectifiers do however suffer from a problematic tradeoff between off-state leakage and forward voltage drop.

Low forward drop Schottky diodes such as shown by curve 7 in FIG. 1F, having voltage drops of 0.2V to 0.3V, can have off state leakage in the range of hundreds-of-microamperes to milliamps (curve 9), and even higher leakage currents at elevated temperatures. Excess Schottky diode leakage current lowers efficiency during converter operation and is especially problematic in any light load or sleep mode conditions where they can discharge a battery over an extended period. The breakdown voltage of a Schottky rectifier is also normally limited to low voltages (curve 8), typically 10 to 30 volts maximum due in part to the abrupt metal to silicon interface and electric field concentration along the interface. The limited breakdown is further exacerbated by an undesirable phenomena know as junction barrier lowering causing a strong voltage dependence in off state leakage, essentially rendering the rectifier unusable at higher voltages. Barrier lowering also results in adverse sensitivity of Schottky leakage current to increases in temperature—leakage further degrading the device's performance as a rectifier. In extreme cases, leaky Schottky diodes can exhibit destructive thermal runaway in their off condition, where leakage leads to localized heating, increased barrier lowering which in turn generates even greater localized leakage current.

Reverse Recovery Losses in Diodes

The aforementioned problem of reverse diode recovery in a rectifier is exemplified by the power stage of a Buck converter as shown in FIG. 2. In circuit 10, power MOSFET switch 11 when conducting supplies current I_{L} to inductor 13 and load 14. Before switching, device under test (DUT) rectifier 12 is off and reverse biased. When MOSFET 11 is switched into an off condition, the current in inductor 13 cannot instantly change, so that the voltage Vx on the cathode of the rectifier instantly drops below ground forward biasing rectifier 12 at a current I_{F} (equal to I_{L} at the time of switching). Thereafter any attempt to turn on switch 11 will result in a momentary spike of current I_{RR} to discharge the stored charge in rectifier 12. The peak magnitude of this current spike depends on the rate that MOSFET 11 is turned on, and the amount of charge stored in rectifier 11.

This “reverse recovery” phenomenon is better understood by representing circuit 10 by an equivalent circuit 20 applicable during the diode reverse recovery period. In this circuit, the steady state current in inductor 13 is represented by constant current source 22. Rectifier 12, schematically represented by diode 24 and parallel capacitor 25, illustrates stored charge in the conducting diode represented by nonlinear capacitor 25. Prior to reverse recovery, the current conducting through diode 24 forces inductor voltage Vₓ to a potential one diode drop (i.e. V_{F}) below ground. Upon turning on MOSFET 11, the drain-to-source voltage across MOSFET 11 forces the device into saturation, whereby MOSFET 11 acts as a time-varying current source 21, the current changing as the gate voltage on MOSFET 11 changes.

The electrical response to this transient condition is illustrated for three different device types in FIG. 2C as a plot of diode cathode current and diode voltage versus time. In the initial condition prior to switching the rectifier conducts forward current 31 at a forward bias 32. At time t₁, the forward diode current 33 decreases at a constant slew rate until the polarity of diode current crosses zero. The resultant waveforms vary depending on the type of rectifier and the amount of stored charge in the device.

In ideal device 1, as soon as the diode current hits zero the diode voltage rises immediately to V_{DD} (curve 34) and the current remains at zero, never reversing polarity. Since the current is already zero when the voltage increases across the rectifier, no power is lost. Unfortunately no available semiconductor rectifier today behaves with such an ideal characteristic.

In device 2, the current in the rectifier reverses direction (curve 35) until it hits peak reverse current I_{RR}, then decays to zero (curve 37). The area under the curve (area 38), the area bounded by 35 and 37, is equal to the stored charge Q_{RR} in the rectifier (note: the time integral of current has units of charge, i.e. coulombs). During diode recovery of device 2, the diode voltage rises from −V_{F} to V_{DD} according to curve 36. Since current is flowing while voltage is present, power loss occurs in the rectifier. The power loss varies by the rate the voltage rises and the current decays, namely

P_{RR}=∫[I_{RR}(t)·V_{rect}(t)]dt

While the reverse recovery power loss is easy to specify mathematically, in practice its prediction a prior/is difficult and complex since it depends on diodes properties such as the voltage ramp rate (or “snappiness”) of the diode resulting from three-dimensional minority carrier recombination effects within the device, from stray inductance in the circuit and package, and complex electro-thermal interactions. In general, however, rectifiers that store more charge will suffer greater reverse-recovery losses.

In contrast to the lossy diode recovery of device 2, a fast recovery diode such as a the one exemplified by the curves identified as rectifier device 3, exhibits reduced significantly lower reverse currents illustrated—a fact illustrated by curves 39 and 40. Such a device also therefore exhibits lower reverse recovery losses and peak reverse current resulting from reduced stored charge 41. The drain voltage recovers quickly (curve 42) and the current decays rapidly 40, and so power loss from reverse recovery is thereby reduced. This behavior is typical of a well-designed Schottky rectifier, the prior leakage and avalanche issues of the silicon Schottky notwithstanding.

In summary, no conventional two-terminal device meets the ideal characteristic of a rectifier, i.e. a device offering low on-state voltage drop, high and robust avalanche breakdown, low off state leakage, low temperature coefficient of leakage, low stored charge, and freedom from thermal runaway. The only present-day method to eliminate the aforementioned technology limitations of two terminal rectifiers is to employ an active device, i.e. a transistor, in place of (or in addition to) the rectifier. Such a device typically includes a third terminal as a gate (a control input) to determine when low-loss conduction and when off-state blocking is to occur. This circuit approach is known as synchronous rectification.

Synchronous Rectification

As illustrated in a Buck converter example of FIG. 3A, circuit 50 comprises a power MOSFET switch 51 driving inductor 54 and filtered by capacitor 55. Rectifier diode 53 is anti-parallel (i.e. in parallel to but in a normally non-conducting reverse-biased polarity) to synchronous rectifier MOSFET 52. Both transistors are controlled by break-before-make (BBM) circuit 56 such that MOSFET 51 conducts whenever rectifier 53 is forward biased and, in this example, whenever MOSFET switch 51 is turned off and interrupts the current flow into inductor 54. Break-before-make circuit 56 must insure that MOSFET 51 and synchronous rectifier MOSFET 52 never conduct at the same time or shoot through current will flow directly from V_{DD} to ground lowering efficiency and potentially damaging the power MOSFETs.

A waveform plotting the potential of voltage Vx versus time shown in FIG. 3B illustrates this voltage alternates between V_{DD} (line segment 51) and a potential −I·R_{DS}, the drop on the synchronous rectifier during conduction (line segment 53). During the transition interval when both transistors are off, the voltage Vx increases to the voltage drop V_{F} across forward biased rectifier 53, carrying the full inductor current (line segments 52 and 54). Unless diode 53 is shunted by a Schottky rectifier (and thereby suffer higher reverse leakage currents), it will store charge during the BBM interval 53 leading to voltage overshoot and oscillations from diode recovery (line segment 55).

As shown in the graph of FIG. 3C, since the voltage drop 62 on the synchronous rectifier I·R_{DS} can be made lower than that of the drop V_{F} across forward biased diode 61; the overall efficiency is improved by the introduction of a synchronous rectifier MOSFET in parallel with the rectifier. The size of the MOSFET must be chosen to adjust the resistance sufficiently low enough to shunt the rectifier, where the size increases with the off state breakdown voltage 60. As long as the portion of the time the synchronous rectifier is conducting is long compared to the BBM interval, the overall conduction losses in the converter are reduced beneficially by the synchronous rectifier.

Frequency Limitations of Existing Rectifier Solutions

At higher frequencies, especially above 2 MHz, two major problems emerge with using a synchronous rectifier. First, the driving the gate capacitance of the synchronous rectifier MOSFET becomes a non-negligible power loss. At low voltages, i.e. under 30 V, a power MOSFET's high input capacitance can be a significant and even dominant component of power loss in a switching converter. Input capacitance of a power MOSFET, measured in units of nano-Farads (or nF), comprises a combination of gate-to-source capacitance, gate-to-channel capacitance, and gate-to-drain capacitance, all of which depend on voltage.

In these power applications, power losses due to the charging and discharging of input capacitance of the power MOSFET switch and the synchronous rectifier MOSFET are typically determined as a function of electrical charge rather than capacitance. By summing, i.e. integrating over time, the input capacitance over a range of bias conditions, the total power needed to drive the MOSFET's gate can more readily be determined. This integral of capacitance over time is a measure of charge, referred to as “gate charge” denoted mathematically as Q_{G}. Because of the large gate width, the gate charge of a power MOSFET can be substantial, typically in the range of tens of nano-Coulombs (i.e. nC). The corresponding “switching” loss driving the switch or synchronous rectifier device on and off with a gate bias V_{GS} at a frequency f, given by Q_{G}·V_{GS}·f, can at megahertz frequencies be comparable to conduction losses arising from device resistance.

Even more problematic, there is an intrinsic tradeoff between conduction and switching losses in a power MOSFET used as the switch or synchronous rectifier in DC-to-DC power switching converters. Assuming fixed frequency operation with variable on-time given by duty factor D, the power loss in the MOSFET can in low-voltage applications be approximated by the equation

P_{LOSS}≈I²·R_{DS}·D+Q_{G}V_{GS}·f

Increasing the transistor's gate bias to reduce on resistance adversely impacts gate drive switching losses. Conversely reducing gate drive improves drive losses but increases resistance and conduction losses. Even attempts to optimize or improve the device design suffer compromises. For example, the gain of the transistor can be increased and its on-resistance for a given size device decreased by using a thinner gate oxide, but the input capacitance and gate charge Q_{G} will also increase in proportion. Note from the above equation, the gate drive losses in any given synchronous rectifier increase linearly with converter frequency.

The second problem in increasing the frequency of switching power supplies using synchronous rectification occurs for very short pulse durations. The most extreme short pulse condition arises whenever high frequency conversion is combined with high duty cycles (e.g. when D>90%, where D is the percent on time of the switch, and [100%−D] is the percent on time of the synchronous rectifier). In such an event, there is simply not enough time to turn the synchronous rectifier on and then off again in the short time in each clock period when rectification is to occur, i.e. during inductor current recirculation.

For example a synchronous Buck converter operating at 1 MHz and 10% duty factor has a clock period of 1 microsecond and therefore only a duration of 100-nsec in which to execute synchronous rectification. If we assume a 10 nsec break-before-make (BBM) interval, 80 nsec remain for synchronous rectification. At 4 MHz, the clock period is 250 nsec and rectification occurs for only 25 nsec, 20 of which are consumed just turning off and turning on the synchronous rectifier. At this condition, very little benefit is gained by synchronous rectification. At 5 MHz and a 90% duty factor, there is no time left for synchronous rectification at all. Hereafter, we refer to this limitation as the “narrow pulse” problem with synchronous rectification.

The only way to perform synchronous rectification at higher frequencies is to limit the maximum duty cycle D to a lower value. Limiting the value of D however restricts the useful voltage conversion range of the converter since in a non-isolated converter D is proportional to the converter's input-output voltage ratio. We can derive the frequency duty-factor limitation by the relation

t_{rect}=[(100%−D)/f]=[t_{syncrect}+2·t_{BBM}]

where t_{rect} is the total time when recirculation through the rectifier occurs, which by definition is (100%−D) of the total clock period (1/f). Likewise, the total rectifier time comprises synchronous rectifier time and break-before-make time for both MOSFET turn-on and turn-off. Rearranging we see

D<100%−[f·(t_{syncrect}+2−t_{BBM})]

which means the maximum duty factor is reduced with increasing frequency. This relationship is plotted in FIG. 3D as a function of the total rectifier time, i.e. the time when the Buck switch is off and the rectifier or synchronous rectifier carries the inductor current. Accordingly, a total rectifier interval of 30 nsec (e.g. where t_{syncrect}=10 nsec and t_{BBM}=10 nsec) has a maximum duty cycle of 94% at 2 MHz, of 85% at 5 MHz, 70% at 10 MHz, and only 55% at 15 MHz.

Restricting the maximum duty cycle of a switching regulator limits its useful range of applications. For example, in a Buck converter D=(Vout/Vin). Combining this equation with the maximum duty factor condition above yields the relation

Vout<Vin{100%−[f·(t_{syncrect}+2·t_{BBM})]}

In the common application where the input to a step down regulator is the lithium ion battery, the input varies during discharge from 4.2V to 3.0V. The 3V input condition represents the maximum conversion ratio and duty factors required for any given output. For a converter with 30 nsec minimum rectifier time, the maximum output voltage at 4 MHz is duty cycle limited at 88% to 2.64V, below the popular 2.7 V power supply voltage. At 10 MHz, the maximum duty factor is 70% and the maximum regulated voltage is limited by the duty factor to 2.1 V. At 20 MHz, the maximum regulated output voltage drops to 40% of the 3V input or 1.2V.

Considering the difficulties in timing control of a synchronous rectifier and the limitations imposed on maximum duty factor and output voltage, a two-terminal rectifier has the capability of working at higher frequencies than a three terminal device requiring active gate control. Unfortunately, present-day two-terminal rectifiers exhibit higher conduction losses than synchronous rectifiers since their voltage drop doesn't scale linearly with area as a MOSFET does.

What is needed is a rectifier that can scale to lower voltage drop than silicon Schottky diodes capable of operating at high frequencies without suffering excess leakage, problems from stored charge, diode recovery thermal runaway, and excessive temperature dependence. Ideally such a rectifier could be merged into an efficient synchronous rectifier with minimal stray series inductance. Such a merged rectifier and synchronous rectifier should ideally be capable of operating efficiently at higher frequencies than today's silicon power MOSFETs without imposing limitations on duty cycle and conversion ratios. Moreover, an intelligent algorithm or adaptive circuit is needed to dynamically determine when synchronous rectification is needed and when it is not beneficial or even possible.

### SUMMARY OF INVENTION

An Enhancement-Mode MESFET as a Rectifier

One aspect of the present invention provides a MESFET rectifier. Typically, the MESFET rectifier is fabricated as an N-channel MESFET device with a drain region surrounded on both sides by source regions. Trenches on each side of the drain region separate the drain region from the adjacent source regions. The drain region includes a drain contact and the source regions have respective source contacts. Schottky metal overlays the trench and a gate contact is formed over the Schottky metal. A wire or other method is used to connect the gate contact to either the source contact of the drain contact (since the device is symmetrical).

The resulting device has two terminals—a source terminal and a drain terminal and acts as a diode. A small forward voltage (typically 0.3V) results in a forward current. This current comprises two components—a small forward biased gate current and a larger channel current resulting from the forward biasing of the gate. Since the MESFET's channel-current contributes, i.e. adds, to the gate current, the resulting voltage drop is substantially lower than the Schottky gate current itself which may be 0.5 to 0.7 volts. The voltage drop of the two-terminal MESFET rectifier therefore has a lower voltage drop and a power loss less than a Schottky diode constructed with the same material.

### The Zener Protected Two-Terminal MESFET as Schottky Rectifier

One possible enhancement of the MESFET rectifier is to connect it in parallel with a Zener diode. Addition of the Zener protects the MESFET when the rectifier is reverse-biased. In the forward biased direction, the Zener diode, MESFET rectifier, and Schottky gate all become forward biased, but since the MESFET has a lower voltage drop, it carries most of the forward current with no stored charge.

Since it is difficult to implement a Zener diode in GaAs, its monolithic integration into the rectifier MESFET is problematic. A more straightforward approach is to fabricate the Zener in silicon and to co-package the rectifier MESFET with its Zener protective clamp.

### The Schottky Rectifier Mode in a Synchronous Rectifier MESFET

Another aspect of the present invention provides a merged device includes a synchronous rectifier connected in parallel with the MESFET rectifier described above. A device of this type has two modes of operation. In the first mode of operation, the synchronous rectifier is enabled and the voltage drop over the merged device is minimized. In the second mode of operation, the synchronous rectifier is disabled and the voltage drop over the merged device is equivalent to the voltage drop over the MESFET rectifier.

The dual mode device is ideal for use in switching regulators—as switching frequencies increases, it become increasingly difficult to enforce break before make (BBM) operation of high and low-side switches. This occurs because BBM operation requires deadtime (i.e., time in which both the high and low-side switches are off) and the amount of time available for this state shrinks as switching frequency increases. The same result occurs as duty-cycle of a switching regulator increases—time available for deadtime decreases. The dual mode device accommodates operation where the combination of duty-cycle and switching frequency prevent proper BBM operation by allowing the synchronous rectifier to be disabled. With the synchronous rectifier disabled, the MESFET rectifier provides rectification without the need for switching or deadtime.

For a preferred implementation, the synchronous rectifier is implemented as an N-channel MESFET monolithically integrated with a MESFET rectifier. These two devices are wired in parallel with a separately integrated Zener diode and included in the same package.

### Timing of Synchronous Rectifier MESFET Operation

The present invention provides several methods for operation of the synchronous rectifier described above. For one such method, the converter “switch” is turned on and remains on as long as a PWM control output stays high. To avoid shoot through, the method then waits for a preset duration (t_{BBM}). After waiting, the method tests the PWM control signal. If it is low, the synchronous rectifier is activated and remains on until the PWM control signal goes high. The method then waits for the present duration (t_{BBM}) and begins another cycle by turning the switch on.

### DESCRIPTION OF FIGURES

FIG. 1 Various rectifier diodes (A) simplified construction of silicon P-N rectifier diode (B) schematic representation of silicon P-N rectifier diode (C) I-V characteristics of silicon P-N rectifier diode (linear scale) (C) simplified construction of metal-to-silicon Schottky rectifier diode (D) schematic representation of metal-to-silicon Schottky rectifier diode (E) I-V characteristics of metal-to-silicon Schottky rectifier diode (linear scale).

FIG. 2 Reverse recovery of rectifier in Buck converter example (A) schematic (B) electrical equivalent circuit during diode recovery (C) switching waveforms.

FIG. 3 Synchronous rectifier MOSFET in synchronous Buck converter example (A) circuit (B) switching waveforms (C) I-V characteristics (D) duty factor limitations vs. frequency.

FIG. 4 Enhancement-mode power MESFET (A) device cross section (B) equivalent schematic (C) I-V characteristics (D) gate-only versus threshold two-terminal I-V characteristics (E) active (three-terminal) vs. threshold-connected I-V characteristics.

FIG. 5 Two-terminal MESFET with integrated power Schottky (A) equivalent schematic (B) I-V characteristics (C) alternate schematic representation (D) cross section (E) cross section with enlarged Schottky.

FIG. 6 Two-terminal MESFET with integrated power Schottky and protection Zener (A) schematic (B) reverse mode with avalanche (C) forward mode with Schottky conduction (D) I-V characteristics.

FIG. 7 Synchronous rectifier MESFET with integrated rectifier MESFET and protection Zener (A) equivalent schematic (B) I-V characteristics (C) paralleling of rectifier and synchronous rectifier MESFETs during break-before-make interval (D) cross section of merged device.

FIG. 8 High frequency synchronous Buck converter comprising MESFET switch, synchronous rectifier MESFET, rectifier MESFET, Zener protection, and gate drive circuitry (A) schematic including minimum pulse width control feature (B) Voltage waveform for normal operation (C) voltage waveform for high duty factor operation (D) voltage waveform for short clock periods.

FIG. 9 Algorithm for synchronous rectifier operation with minimum pulse width control (A) Synchronous rectifier turn-on set by PWM control signal masking (B) Synchronous rectifier turn-on set by timer.

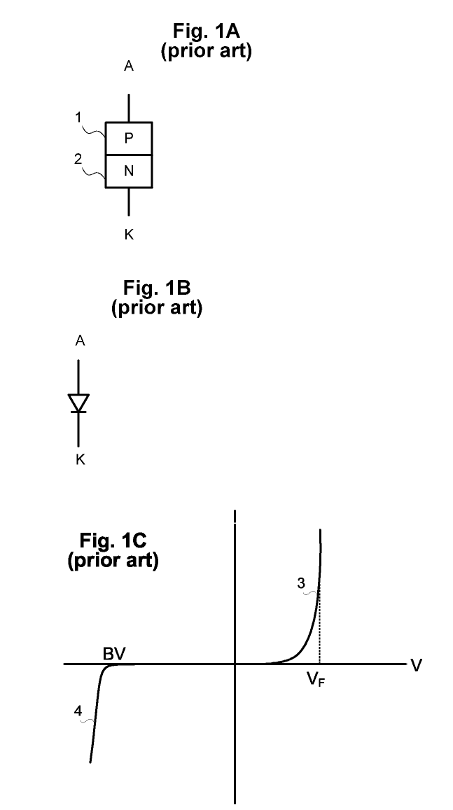

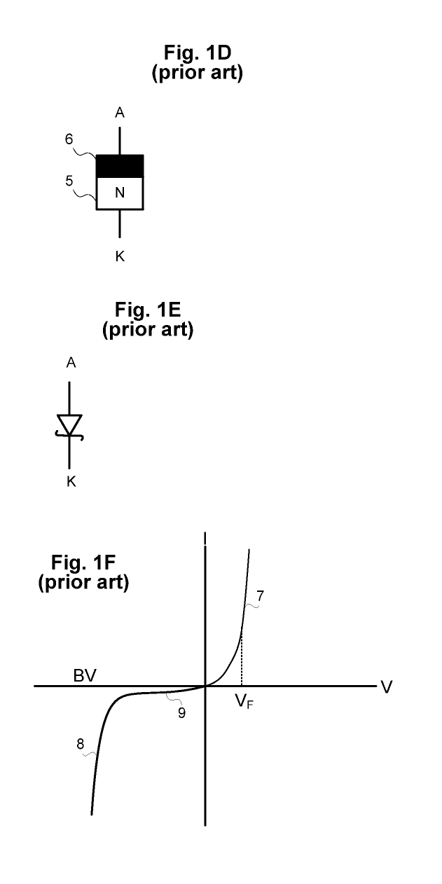

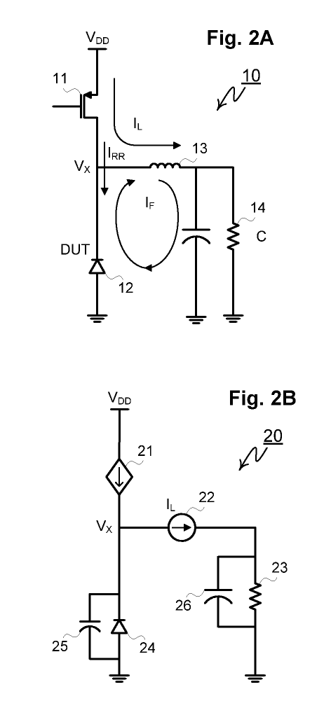

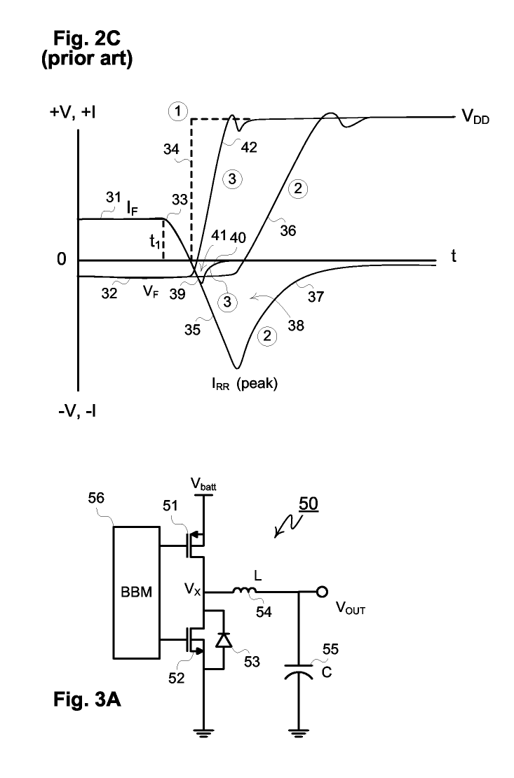

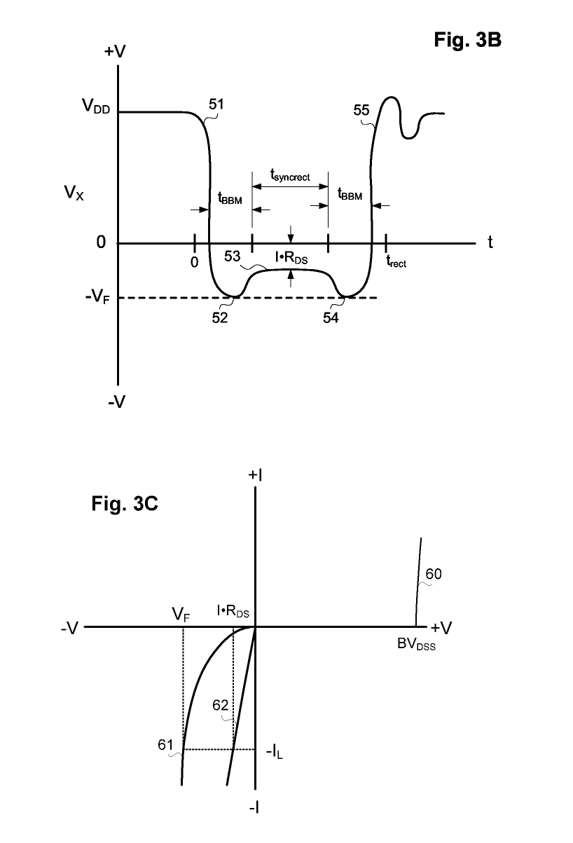

### DESCRIPTION OF INVENTION

Adapting MESFETs for efficient, robust, and reliable operation as rectifiers and as synchronous rectifiers for use in switching power supplies requires innovations and inventive matter regarding both their fabrication and their use. These innovations are described in the related patent applications previously identified. The design and fabrication of power MESFETs for low noise, high frequency operation with rugged avalanche characteristics, especially for use as rectifiers and synchronous in switching converters at frequencies beyond that of normal silicon MOSFETs capabilities, requires inventive matter, which is the main subject of this invention disclosure.

In another embodiment of this invention, a new MESFET merged device is optimized and used to perform both two-terminal Schottky rectification and synchronous rectification in the same device. In another embodiment of this invention, a gate control method and algorithm is used to switch between rectifier and synchronous rectifier mode to depending on duty factor and switching frequency to optimize converter efficiency over a wide range of operating conditions.

### An Enhancement-Mode MESFET as a Rectifier

From the disclosure background of this application, no silicon based device, be it P-N junction rectifier, Schottky rectifier, or synchronous rectifier MOSFET meets the electronics industry's need to increase frequency in modern DC-to-DC converters and switching voltage regulators. Higher frequency is fundamental to improve transient response and to decrease inductor size in such circuits, but using today's available silicon based devices requires circuit and system designers sacrifice efficiency for the sake of size. While devices such as silicon-carbide, indium phosphide, and other compound semiconductor materials have been discussed academically as possible future power devices, their cost, performance, material issues, and reliability compromises were found to be unacceptable for meeting consumer expectations in today's demanding markets of mobile communication, computing and entertainment.

One device technology platform discarded by the semiconductor industry for power applications (other than RF) was that of the gallium arsenide MESFET. Historically “MESFETs”, an acronym for metal-epitaxial-semiconductor field effect transistor, have been applied as an active device only to radio frequency (RF) power amplification and RF signal routing. In contrast to the insulated-gate silicon MOSFETs, MESFET implementation has been largely achieved with gallium arsenide (GaAs), a man-made semiconductor with good properties for high frequency operation. But since GaAs does not produce a stable high-quality dielectric from thermal oxidation or nitridization, its use in other applications has been ignored for a number or reasons. These reasons include:
(1) The GaAs MESFET is a normally on, i.e. a depletion mode, device. Power electronics and DC-to-DC switching converters need a normally-off (i.e. an enhancement mode) device to operate safely and reliably.
(2) GaAs MESFET exhibit destructive avalanche properties and fragility in surviving voltage spikes.
(3) MESFETs are designed for optimal RF characteristics and minimal capacitance, not for power applications requiring minimum resistance and superior current uniformity.
(4) In RF applications, MESFETs are traditionally biased at a fixed gate voltage and then varied by introducing a small signal input on top of the DC bias, not switched between on and off states in a digital manner. MESFET gate control for digital operation requires special circuitry not to overdrive the gate and potentially damage the device.
(5) Even in an enhancement mode MESFET, a zero volt bias may be inadequate to fully turn-off the device to suppress drain leakage current.
(6) MESFETs are non-isolated devices making it difficult to monolithically integrate multiple devices or to benefit from matched device properties and low parasitics. Isolation requires deep expensive mesa etching resulting in a non planar surface not amenable to metal interconnection.

Without addressing all or most of these issues, MESFETs are not suitable for power electronics, and especially for DC-to-DC conversion. If these issues are collectively addressed, however, the MESFET once adapted for power applications offers numerous advantages over silicon power MOSFETs and other devices, including low gate drive voltages, low input capacitance for a given resistance MESFET switch, and the potential for implementing very high frequency DC-to-DC converters with very small inductors.

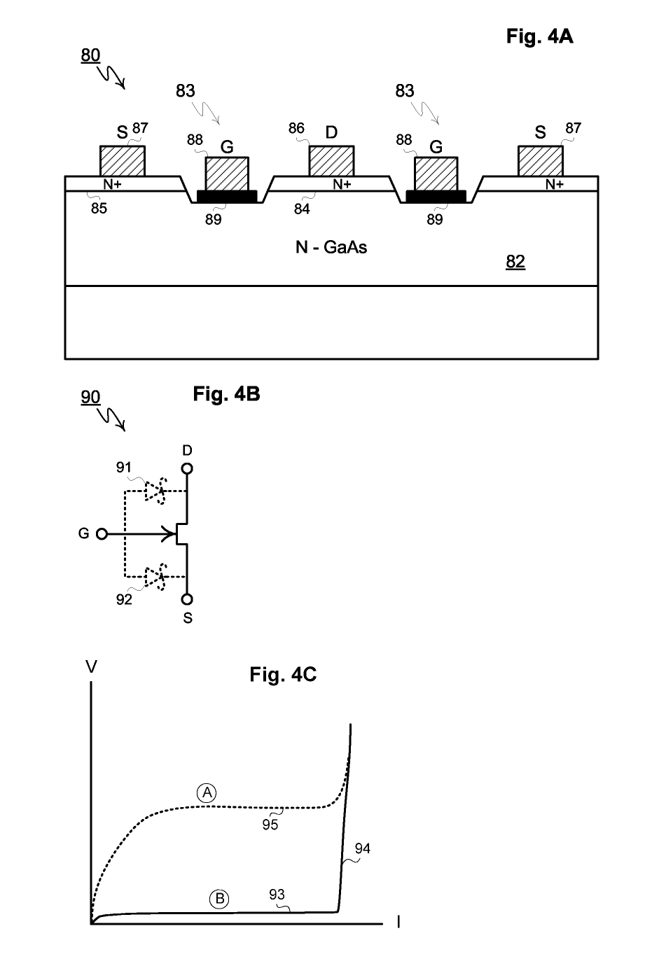

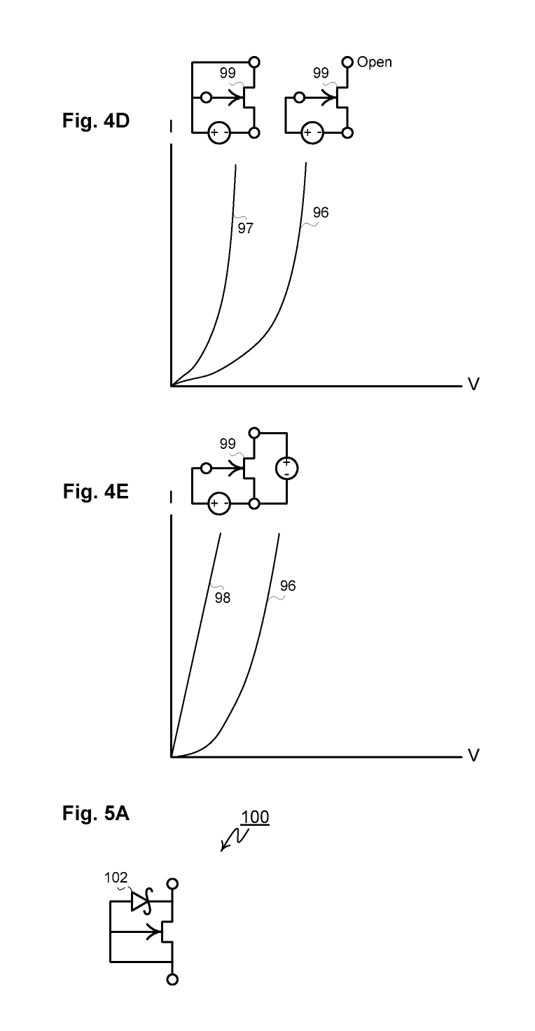

In this particular inventive embodiment, the utility of the device for rectification is beneficial for low capacitance, no stored charge, low on-state voltage drop, and the prospect for integration into a synchronous rectifier also implemented using a GaAs MESFET. An example of a power MOSFET applicable for rectification is shown cross FIG. 4A. In device cross section 80, MESFET N+ drain region 84 and drain contact 86 is surrounded by concentric gate comprising trench 83 and Schottky gate metal 89 spaced from trench sidewall by a gap or optionally by a sidewall dielectric. N+ source 85 and source contact 87 surrounds the concentric gate. The channel is formed in epitaxial layer 82 formed atop semi-insulating GaAs layer 81. The thickness of epi layer 82 is adjusted to make the threshold of MESFET 80 slightly positive or near zero volts.

FIG. 4B illustrates a schematic representation of the MESFET including active device 99 and the intrinsic Schottky gate represented as Schottky diode 92 between gate and source, and Schottky 91 between gate and drain. The drain-current versus drain-voltage (I-V) characteristics of the enhancement mode MESFET shown by curve 93 (device B) of FIG. 4C is contrasted to the more conventional depletion mode MESFET characteristic of curve 95 (device A). Avalanche breakdown 94 occurs at a higher voltage but may be destructive.

Adapting an enhancement mode power MESFET into a rectifier involves connecting the device in a two-terminal configuration, where the gate is shorted to either the source or the drain terminal (since the device as shown is symmetric the nomenclature is arbitrary). The resulting conduction characteristic is illustrated by curve 97. For GaAs, this turn on “threshold” characteristic is typically 0.3V. This current comprises two components—a small forward biased gate current and a larger channel current resulting from the forward biasing of the gate. Since the MESFET's channel-current contributes, i.e. adds, to the gate current, the resulting voltage drop is substantially lower than the Schottky gate current itself depicted by curve 96, which may be 0.5 to 0.7 volts. The voltage drop of the two-terminal MESFET rectifier therefore has a lower voltage drop and a power loss less than a Schottky diode constructed with the same material.

The same MESFET driven by an independent gate voltage, i.e. operated as a three terminal device, has still a lower voltage drop for the same drain current as shown by curve 98 in FIG. 4E when compared against the aforementioned two-terminal “threshold” connection of curve 96, but as a rectifier requires accurate control of timing the gate turn-on (i.e. synchronous operation), which as described previously is problematic for high frequency operation.

So in summary, an enhancement mode MESFET adapted for power operation may be used as a two terminal rectifier (requiring no gate control or critical timing) or may be used as a three-terminal synchronous rectifier, both of which exhibit a lower voltage drop and reduced power dissipation compared to a conventional Schottky rectifier—even one constructed of the same semiconductor material as the MESFET itself. Since the MESFET rectifier's current is majority—carrier channel—current, there is no stored charge in the device, and therefore no reverse recovery loss.

### The Two-Terminal Power MESFET as Schottky Replacement

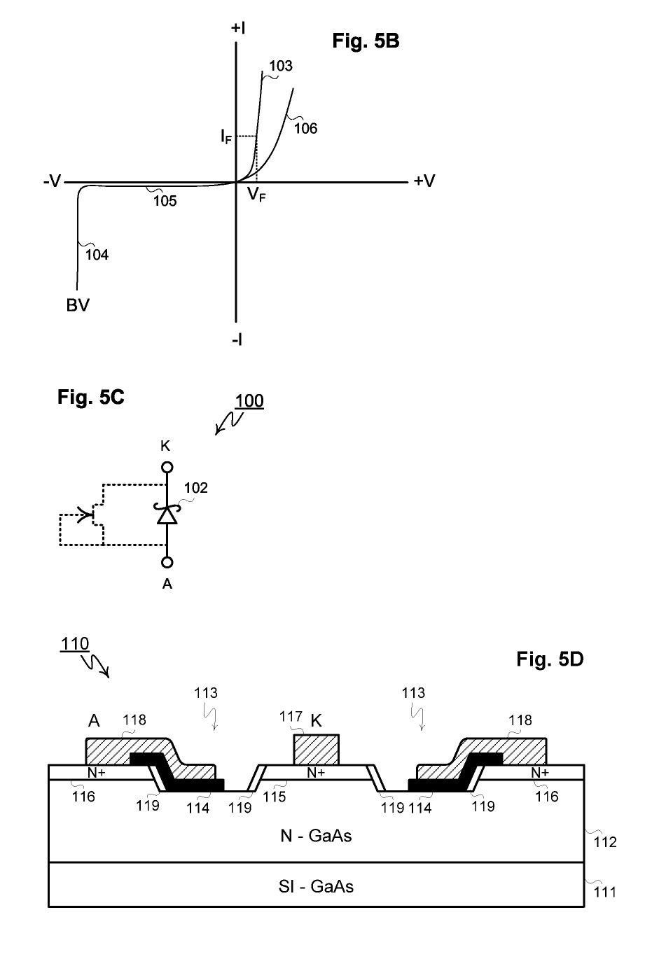

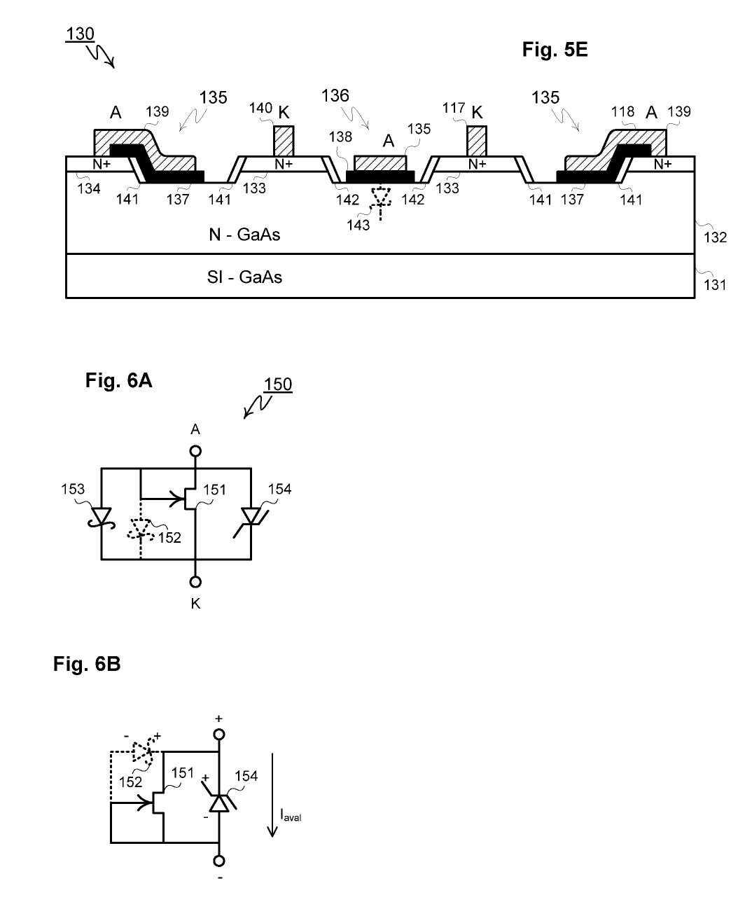

The two-terminal MESFET rectifier is represented schematically in FIG. 5A as an N-channel MESFET 100 with a source-to-gate short (labeled as “A” for anode) and with a Schottky diode 102 connected between the gate and the MESFET's drain terminal (labeled as “K” for cathode). Schottky diode 102 includes the Schottky gate intrinsic to the MESFET itself and may optionally include a parallel Schottky. The parallel Schottky may be monolithically integrated (and optionally merged into) MESFET 100, or implemented as a discrete Schottky. Since the gate of the MESFET is internally shorted to the MESFET's source, it does not require an external connection. The resulting device is a two-terminal rectifier.

The electrical characteristics of the MESFET rectifier are illustrated in FIG. 5B. As a rectifier, the device blocks current in one polarity, namely in quadrant III, i.e. for (−V, −I), and conducts in the other polarity, namely in quadrant I, i.e. for (+V, +I). In the conducting direction, the rectifier conducts according to curve 103 (a curve describing the threshold characteristic of the MESFET) and has a forward voltage drop of V_{F} at a current of I_{F}. In the blocking direction, the off-state leakage of the enhancement mode MESFET is illustrated by curve 105 and varies inversely with threshold voltage and V_{F}. In an unprotected device, breakdown voltage 104 may be destructive and therefore should be avoided in operation.

The overall device behavior as illustrated in FIG. 5C is therefore similar to a Schottky diode 102, although in reality, the conduction occurs substantially through MESFET 100.

One possible construction of the MESFET rectifier is illustrated in cross section 110 of FIG. 5D, where gate 114 is shorted to anode (source) 116 by metal 118, concentrically surrounding and enclosing drain 115 and cathode (drain) metal 117. Using a sidewall spacer process described in the US Patent Application entitled “Rugged MESFET for Power Application.”, Schottky gate metal 114 is separated from the trench sidewall by spacer dielectric 119. Alternatively, spacer dielectric 119 can be eliminated and gate metal 114 spaced inside trench 113 using photomasking and etching.

While separation between Schottky gate 114 and cathode (drain) material 115 is critical to suppress device leakage, the space between source 116 and gate 114 is not since they are shorted together. The entire device is fabricated in epitaxial layer 112 grown atop semi-insulating GaAs substrate 111.

In another embodiment of this invention shown in FIG. 5E, Schottky metal area is larger than that required in implementing the MESFET's gate. In cross section 130, Schottky diode 143 is integrated in extra wide trench region 136 with Schottky metal 138, having tens or hundreds of times larger area than the MESFET's gate 137. Schottky metal 138 and metallization layer 139 together comprise the anode of the device while GaAs epi layer 132, N+ region 133 and metallization layer 140 constitute the diode's cathode. In the layout shown, the cathode of the Schottky surrounds the anode. Schottky metal 138 is spaced from the sidewall of trench 136 by dielectric spacer 142 or by photolithographically forming Schottky metal 138 entirely inside of trench 136.

Integrated in the same GaAs epi layer 132 is a MESFET rectifier, the MESFET comprising Schottky gate metal 137 located within trench 135, sidewall spacer 141, cathode (drain) 133 and anode (source) 134. Metalization layer 139 shorts the MESFET's Schottky metal 137 to its source 134, making the MESFET into a two-terminal rectifier. As shown, MESFET trench 135 is comparable to the area of Schottky diode trench 136 but could alternatively be made larger to enhance the MESFET's channel conduction or smaller to increase the percentage of current carried by Schottky conduction.

In this embodiment of the invention, the MESFET rectifier is connected in parallel to Schottky rectifier 143 by sharing cathode 133 for both devices, and by electrically shorting metallization layers 136 and 139. The entire merged device is made in GaAs layer 132 formed atop semi-insulating GaAs substrate 131. In the embodiment shown, the MESFET rectifier circumscribes and surrounds the Schottky diode. Interconnection can be made using metallization on-chip, or using bond wires.

Like device 110, device 130 includes an unprotected MESFET, and is therefore vulnerable to damage from excess reverse voltages and avalanche breakdown, i.e. whenever the diode's cathode is biased positively with respect to its anode. The MESFET rectifier is self protecting in the opposite polarity since diode and MESFET channel conduction occurs, unless the current density is too high and excessive heating occurs.

The Zener Protected Two-Terminal MESFET as Schottky Rectifier

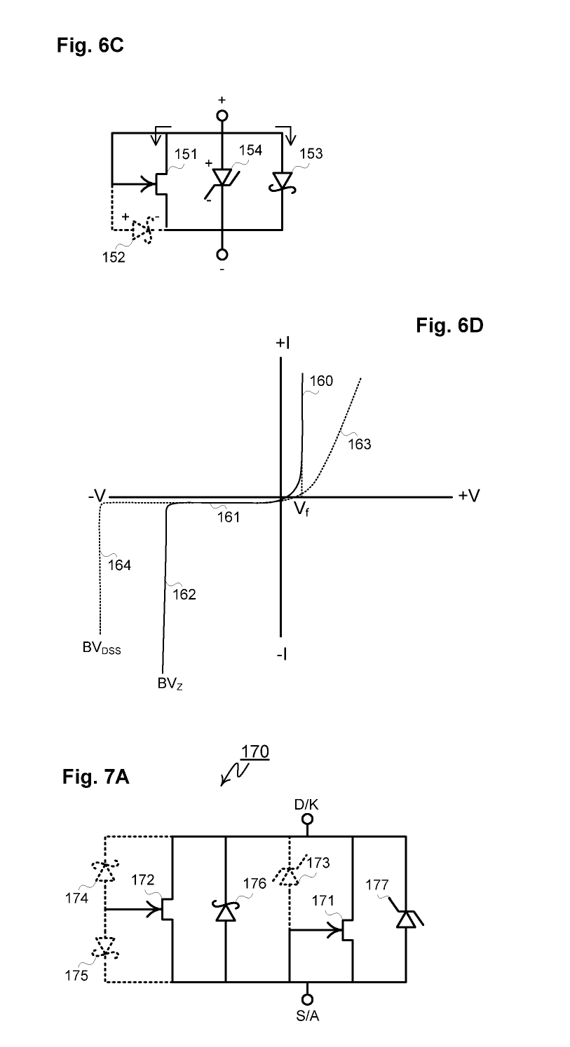

An improved version of the MESFET rectifier is shown schematically in FIG. 6A where in apparatus 150, Zener diode 154 is placed in parallel with MESFET rectifier 151, Schottky gate 152, and optional Schottky diode 153, electrically sharing a common anode. The circuit comprises a Zener-clamped MESFET rectifier.

Operation can be understood by analyzing conduction in two different polarities. In the blocking direction shown in FIG. 6B, an overvoltage condition causes Zener diode 154 to break down and clamp the voltage across MESFET 151, protecting the rectifier and gate Schottky 152 from overvoltage or avalanche.

In the forward biased direction, rectifier Zener diode 154, MESFET rectifier 151, Schottky gate 152, and optional rectifier 153 become forward biased, but since MESFET 151 (and to a lesser extent large area Schottky 153) have lower voltage drops, they carry most of the forward current with no stored charge.

The resulting electrical characteristic is shown in FIG. 6D where the forward conduction voltage V_{F} shown by curve 160 is lower than the Schottky gate characteristic alone, as illustrated by curve 163. In the reverse direction the device leaks current (curve 161) until it reaches the Zener breakdown voltage 162. The Zener voltage 162 must necessarily be lower than the MESFET's fragile BV_{DSS}

Since it is difficult to implement a Zener diode in GaAs, its monolithic integration into the rectifier MESFET is problematic. A more straightforward approach is to fabricate the Zener in silicon and to co-package the rectifier MESFET with its Zener protective clamp.

### The Schottky Rectifier Mode in a Synchronous Rectifier MESFET

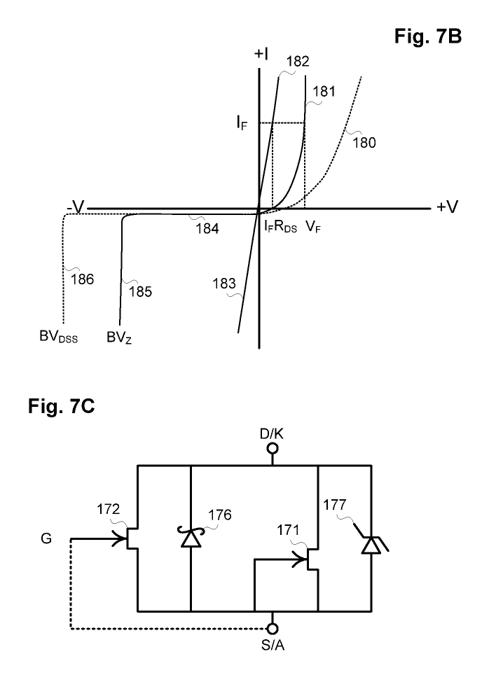

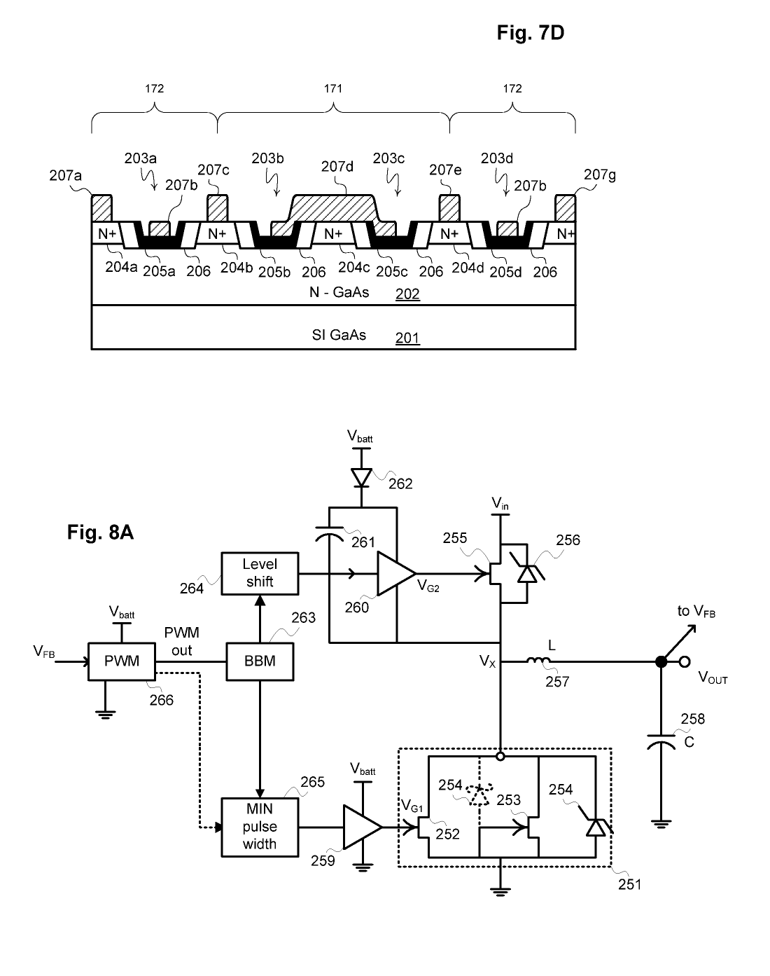

The only way to further reduce the forward voltage drop of the MESFET rectifier device is to integrate it into a synchronous rectifier MESFET as shown in FIG. 7A. In circuit 170, two-terminal MESFET rectifier 171, along with gate Schottky 173, optional Schottky 176 and Zener clamp 177 are wired in parallel with three-terminal MESFET 172. The gate input to MESFET 172 includes intrinsic gate to drain Schottky 174 and gate to source Schottky 175. Ideally synchronous rectifier MESFET 172 and two-terminal rectifier MESFET 171 are monolithically integrated (along with optional Schottky 176). Zener diode, better fabricated in silicon, is connected electrically in parallel to the other components, ideally in a common package.

The electrical characteristics of the merged device are shown in FIG. 7B where the forward conduction (when synchronous rectifier MESFET is off) follows curve 181 and has a forward voltage drop V_{F} at a current I_{F}. When the synchronous rectifier MESFET is on, the device conducts according to curve 182, having a voltage drop at a current I_{F} of I_{F}·R_{DS}, a voltage drop lower than the rectifier MESFET's forward voltage V_{F}. Both curves have a lower voltage drop than the device's Schottky gate alone, shown by curve 180.

In the reverse direction whenever the synchronous rectifier is off, the device has a leakage current 184 and a Zener clamped avalanche voltage 185, which is designed to be lower than the MESFET's potentially destructive BV_{DSS} breakdown.

Curve 183 illustrates that if the synchronous rectifier MESFET is not turned off before the polarity of the applied voltage across the device reverses direction, the synchronous rectifier will undesirably conduct in the reverse direction, lowering efficiency and increasing power losses to potentially damaging levels.

FIG. 7C illustrates that whenever the synchronous rectifier MESFET 172 is shut off by temporarily connecting its gate to its source, it is electrically wired identically to the hard-wired rectifier MESFET 171. The two parallel MESFETs further reduce the forward voltage drop of the rectifier MESFET, since the voltage drop of the MESFET rectifier scales with its channel width, i.e. the size of the MESFET.

One integrated implementation of circuit 170 (without showing optional Schottky 176 or Zener diode 177) is illustrated in FIG. 7D. Specifically, cross section 200 integrates two-terminal rectifier MESFET 171 and three-terminal synchronous rectifier MESFET 172 monolithically without the need for isolation in a common epitaxial layer 202 grown atop a semi-insulating substrate 201. All MESFETs shown contain a trench gate structure with the Schottky gate metal spaced from the trench sidewall, either by physical separation (photolithographically defined) or by sidewall spacer oxide 206 as shown.

In the cross section shown rectifier MESFET 171 is formed with trenches 203B and 203C, Schottky gate metal 205B and 205C, N+ anode (source) region 204C, and interconnection metal 207D. The structure is circumscribed by cathode (drain) N+ regions 204B and 204D and metallization 207C and 207E. Metallization 207D shorts MESFET source 204C to gates 205B and 205C to form the two-terminal MESFET rectifier structure, with no external gate drive required.

Cathode N+ regions 204B and 204D are also surrounded by and electrically shared with synchronous rectifier MESFET 172. The synchronous rectifier MESFET is a three terminal device comprising trenches 203A and 203D, Schottky gate metal 205A and 205D, gate metallization 207B and 207F, N+ source regions 204A and 204E, and source metallization 207A and 207G. The two devices are paralleled by connecting source metal 207A and 207G to anode metal 207D.

### Timing of Synchronous Rectifier MESFET Operation

Whenever synchronous rectification is utilized at high frequencies, especially above a few megahertz, synchronous rectifier MESFET timing and gate control is limited by the “narrow pulse” problem. At multi-megahertz frequencies (where the clock period T is sub-microsecond) a high duty cycle D means switch on time t_{sw} is a significant fraction of the total clock period T. Under such conditions, the time remaining for break-before-make operation t_{BBM} (to prevent shoot-through) and for synchronous rectifier conduction tₛᵣ is limited.

Operation of a switching converter where there is inadequate time to turn-on and turn-off the synchronous rectifier in the time allowed can lead to poor regulation, electrical noise, variable frequency EMI, loss of efficiency, large shoot-through conduction currents between the supply and ground, and potentially even result in damage to a converter's power devices. This challenge is exacerbated in converter's using power MESFETs, since these devices can switch at a much higher frequency than can silicon based transistors and MOSFETs.

As described previously, a synchronous switching converter involves alternating conducting through a “switch” (which lets power into the converter's energy storage elements from its input) and a synchronous rectifier (which forces the converter's output to be DC), separated by brief break-before-make intervals of time (to prevent shoot-through conduction) during which current is carried by a rectifier diode.

Once a synchronous converter has been turned-on when there is inadequate time to turn it off, one of two undesirable scenarios may result. First, if the synchronous rectifier is left on or turned off too slowly while the “switch” is already beginning to conduct, the minimum safe break-before-make (BBM) time has been violated and excessive and potentially damaging shoot-through conduction will result. In a second case, the switch is not allowed to turn-on until the synchronous rectifier is fully turned off, i.e. the BBM interval is guaranteed. The result is the clock period T will be extended in a varying and unpredictable manner, and a variable frequency will result. The varying frequency causes increased ripple on the converter's input or output and leads to variable frequency noise—noise difficult to filter or avoid.

The solution is to determine whether there is adequate time to use the synchronous rectifier, i.e. to safely turn it on and off, and if sufficient time is not available, to avoid turning on the synchronous rectifier at all during until it is safe to do so. In other words, if adequate time is not available to use the synchronous rectifier (the narrow pulse problem), leave the synchronous rectifier off and rely on conduction through a two-terminal rectifier which requires no gate control to operate.

In the case of the disclosed power MESFET device and its operation, this approach is made easier by the integration of a two terminal MESFET rectifier inside a three-terminal MESFET synchronous rectifier. The merged device also benefits from lack of stray inductance, allowing switching and state transitions with minimal noise and overvoltage “ringing”.

The challenge lies in how to anticipate whether adequate time exists to use the synchronous rectifier or to leave it off. To accomplish this task, a new “minimum pulse width” drive circuit must be added to the signal path driving the gate of the synchronous rectifier. The goal of this circuit is to prevent undesirable turn-on of the synchronous rectifier. This task is “predictive” since an estimate of the time available in a future clock cycle can only be based on past information. Since prediction of the future based on past data is imperfect, some tolerance for error must be included.

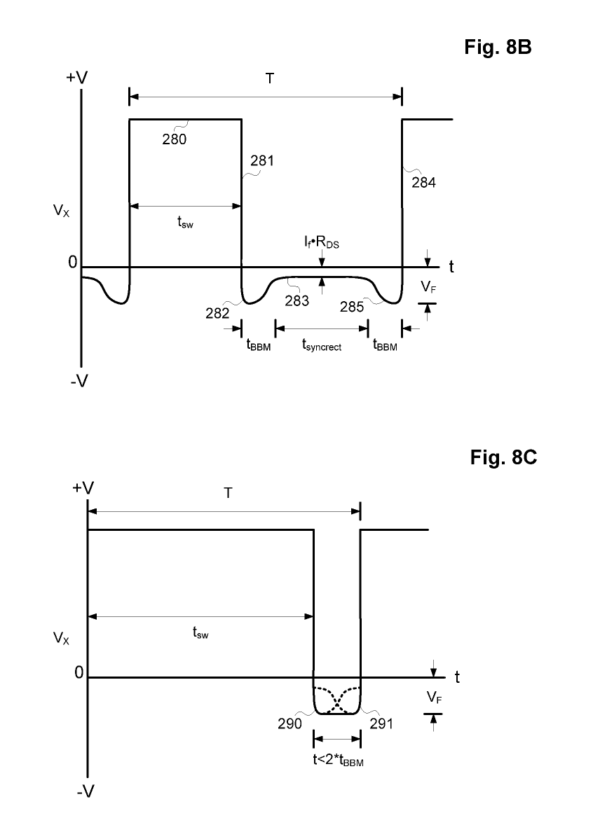

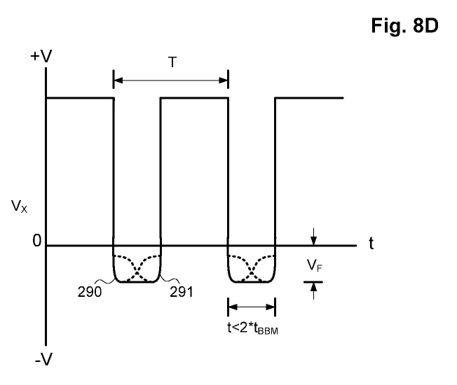

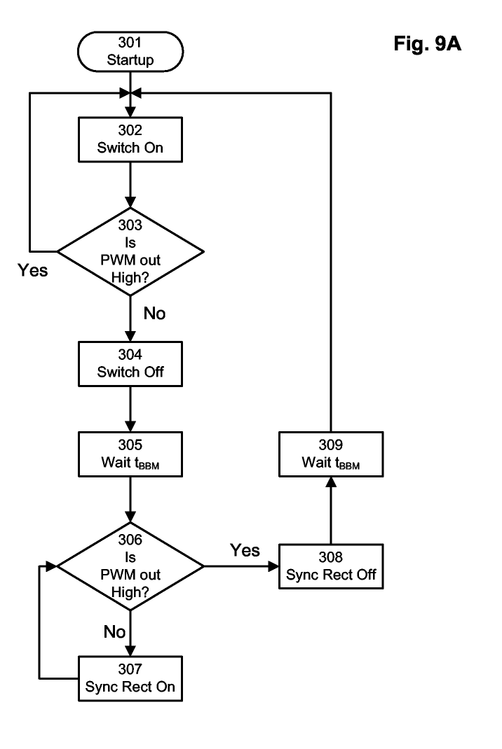

A synchronous Buck converter (for stepping down and regulating DC voltages) using power MESFETs and including the “minimum pulse width” (hereafter MPW) function as described is shown in FIG. 8A. In circuit 250, PWM control 266 drives a high-frequency push-pull power half-bridge comprising N-channel MESFET switch 255, and merged MESFET rectifier and synchronous rectifier 251, where said half-bridge controls the current in inductor 257 to regulate the voltage across output capacitor 258. The PWM (or in some cases PFM) signal output from control circuit 266 drives break-before-make (BBM) circuit 263 which is used to drive the power MESFETs at high frequencies without shoot-through current.

High side drive of power MESFET switch 255 is accomplished by floating gate buffer circuit 260 powered by bootstrap capacitor 261 and bootstrap diode 262. Circuit 260 and bootstrap capacitor 261 are referenced to Vx, the source of high side N-channel MESFET switch 255. MESFET 255 is optionally protected by Zener diode 256. The low-voltage output of BBM circuit 263 is level shifted by circuit 264 to drive the input of gate driver 260. The output of gate driver 260 is limited in voltage so that (V_{G2}−Vₓ) is restricted to some predetermined maximum value, e.g. 0.5V or 0.6V. This voltage clamped (or alternatively, current clamped) gate driver is needed to minimize gate drive current and associated power losses, and to avoid damaging the MESFET's Schottky gate input, as further disclosed in US patent application entitled “High Frequency Power MESFET Gate Drive Circuits” included herein by reference.

Low-side drive of power MESFET synchronous rectifier 252 is performed by gate buffer 259 powered directly from the converter's input V_{batt}. Like gate buffer 260, gate driver 259 is a voltage clamped (or current clamped) high speed gate drive circuit with an output voltage V_{G1} limited to some prefixed value, typically 0.5V to 0.6V to prevent overdrive of MESFET 252. Synchronous rectifier 252 is wired in parallel with the two-terminal MESFET rectifier 253 and its intrinsic gate Schottky diode 254, and protected by the parallel connected Zener diode clamp 254 to restrict the maximum drain-to-source voltage imposed across MESFETs 252 and 253. The combination as one protected device is represented by box 251 enclosing GaAs MESFETs 252 and 253, and Zener 254, which is integrated in a silicon IC, not in the GaAs chip. MESFET rectifier 253 clamps the maximum below-ground potential to a value V_{f} during break before make intervals when synchronous rectifier MESFET 252 is still off.

The input signal for synchronous rectifier 252 comes from PWM circuit 266 through BBM circuit 263 and through said minimum pulse width (MPW) circuit 265. The function of MPW circuit 265 is to prevent buffer 259 from turning on synchronous rectifier 252 unless adequate time exists to do so. Various circuits and algorithms may be used to implement the MPW function including counters, logic gates, sample and hold techniques and more.

The resulting waveforms are shown in the plots of Vₓ versus time in FIGS. 8B, 8C and 8D. In FIG. 8B where the duty factor is low and the period T is relatively long compared to the break-before-make interval t_{BBM}, line segment 280 represents the time t_{sw} when high side switch 255 is on. Line segment 281 illustrates the inductor voltage immediately flies below ground when switch 255 is turned off. Immediately thereafter (segment 282) the two-terminal MESFET rectifier 253 clamps the maximum negative going transient to a voltage V_{f} for the interval t_{BBM} before synchronous rectifier 252 can be turned on.

Line segment 283 illustrates conduction of the synchronous rectifier 252 at a voltage I_{F}·R_{DS}, which is less than V_{F} of the rectifier MESFET 253. After a time t_{SR}, synchronous rectifier is turned off. For a duration t_{BBM} (segment 285) both MESFETs remain off till the switch is turned back on and the voltage at Vx is pulled high (segment 284).

In contrast to this waveform, in FIG. 8C the on-time for the high side switch t_{sw} is increased to a larger percentage of the period T, i.e. a high duty factor, so that little time remains for rectification. Since the sum of the break before make interval 290 and 291, consume the whole narrow pulse duration, no time is left for synchronous rectification and so it is never turned on.

Similarly in FIG. 8D the same narrow pulse condition arises, not because an extreme duty factor but just because the converter is operating at a higher frequency, i.e. a shorter period T than the prior examples. Again the sum of break-before make intervals 295 and 296 consume the entire pulse width so no time is left for synchronous rectification and the low side MESFET 252 remains off.

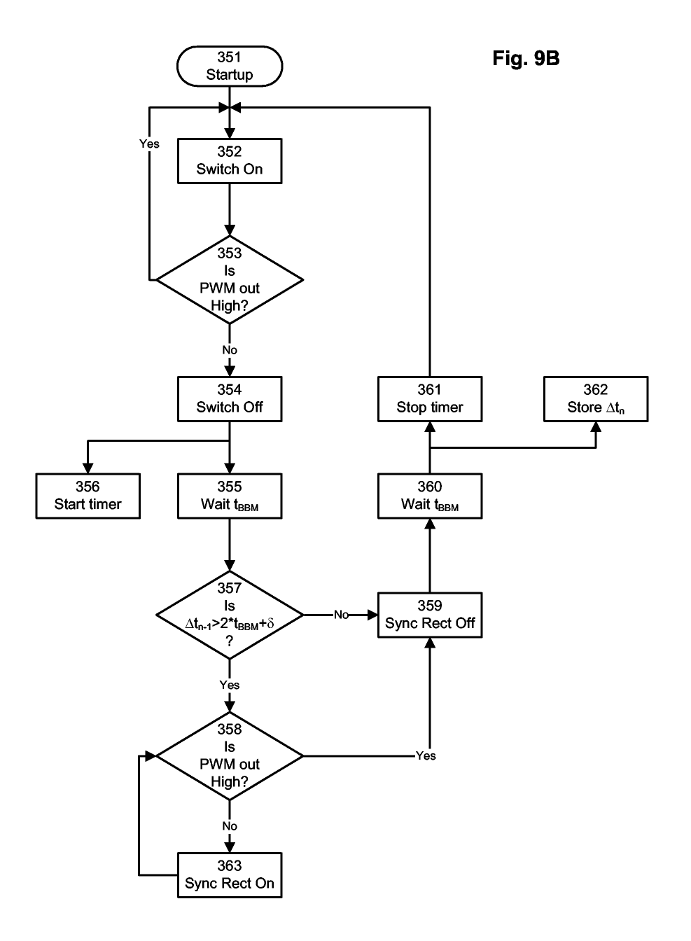

Several algorithms may be employed to implement MPW control of the synchronous rectifier device. Flowchart 300 shown in FIG. 9A illustrates after startup (step 301), the converter “switch” is turned on (step 302) and will remain on as long as the PWM control output stays high (step 303). When the PWM output drops low the switch is turned off (step 304) whereby the inductor forces the node voltage Vx to forward bias the rectifier. To avoid shoot through the synchronous rectifier waits for a time t_{BBM} (step 305) and if the PWM output is still low (step 306) the synchronous rectifier is turned on (step 307) and remains on until the PWM control changes to a high state. At the time, the synchronous rectifier is turned off (step 308) forcing conduction through the rectifier again. After a time interval of t_{BBM} (step 309), the converter switch is once again turned on (step 302) and the cycle repeats itself.

In this approach the MPW control is achieved by preventing the turn-on of the synchronous rectifier if the PWM control has changed state during the break-before-make interval.

Another approach to determine if the synchronous rectifier should be turned on (or not) is shown in FIG. 9B. In flowchart 350 similar to the prior algorithm, startup 351 is followed by turning on the switch (step 352) and continuing to keep the switch on till the PWM controller changes state (step 353) and shuts it off (step 354).

At this point, a timer is started (step 356) and the break-before-make shoot-through protection is performed in tandem (step 355). This timer is used to measure the time Δt when the switch is off, i.e. the time duration (T−t_{sw}). This duration must be measured in a previous cycle for use in the decision making of the current cycle, but on the initial cycle the register can be preloaded with some assumed value.

Next the stored time Δtₙ₋₁ (from the previous n−1 cycle) is compared to twice the break-before make interval (step 357) to determine if

Δtₙ₋₁>2·t_{BBM}+δ

If the time Δtₙ₋₁ is some interval δ longer than twice the BBM operation, then there is adequate time to turn-on the synchronous rectifier (step 358), and if the PWM control output is still low (step 358) then the synchronous rectifier should be turned on (step 363) and left on until the PWM control signal goes high.

If either Δtₙ₋₁ is shorter than twice the BBM operation (plus some interval δ) or the PWM signal goes high, then the synchronous rectifier is turned off (step 359) and after the break before make interval t_{BBM}, the timer is stopped (step 361), stored as the time Δtₙ (step 362), and the switch is turned on (item 352) to be repeated again.

Alternatively the on time of the switch t_{sw} can be counted and used to decide if the time is adequate to turn on the synchronous rectifier.

What is claimed is:

1. A two-terminal MESFET rectifier which includes:
a first drain;
a first gate; and
a first source electrically connected to the first gate.

2. A rectifier as recited in claim 1 where the MESFET is an enhancement-mode N-channel device.

3. A rectifier as recited in claim 1 that is fabricated using gallium arsenide (GaAs) as a semiconductor material.

4. A rectifier as recited in claim 1 that is fabricated using indium phosphide (InP) as a semiconductor material.

5. A rectifier as recited in claim 1 that further comprises a metallization layer that electrically connects the first gate to the first source.

6. A two-terminal MESFET rectifier which includes:
a first drain;
a first gate;
a first source electrically connected to the first gate; and
a Schottky diode connected to the first source and first gate.

7. A rectifier as recited in claim 6 where the MESFET rectifier is an enhancement-mode N-channel device.

8. A rectifier as recited in claim 6 that is fabricated using gallium arsenide (GaAs) as a semiconductor material.

9. A rectifier as recited in claim 6 that is fabricated using indium phosphide (InP) as a semiconductor material.

10. A rectifier as recited in claim 6 that further comprises a metallization layer that electrically connects the first gate to the first source.

11. A two-terminal MESFET rectifier which includes:
a first drain;
a first gate;
first source electrically connected to the first gate; and
a Zener diode connected to the first source and first gate.

12. A rectifier as recited in claim 11 where the MESFET rectifier is an enhancement-mode N-channel device.

13. A rectifier as recited in claim 11 that is fabricated using gallium arsenide (GaAs) as a semiconductor material.

14. A rectifier as recited in claim 11 that is fabricated using indium phosphide (InP) as a semiconductor material.

15. A rectifier as recited in claim 11 that further comprises a metallization layer that electrically connects the first gate to the first source.

16. A rectifier as recited in claim 11 where the Zener is fabricated using silicon as a semiconductor material.

17. A rectifier as recited in claim 11 that further comprises a Schottky diode connected to the first source and first drain.

18. A rectifier as recited in claim 11 where the majority of off-state avalanche current flows through the Zener.

19. A rectifier as recited in claim 11 where the breakdown voltage of the Zener diode is substantially less than the avalanche breakdown of the MESFET.

20. A rectifier as recited in claim 11 where the majority of forward bias current is conducted through the MESFET rectifier and not through the forward bias of the Zener diode.

21. A rectifier as recited in claim 11 where the majority of forward bias current is conducted through the parallel combination of MESFET rectifier and Schottky diode.

22. A three-terminal MESFET rectifier that comprises:
a first MESFET rectifier that includes: a first drain, a first gate, and a first source electrically connected to the first gate, and
a second MESFET synchronous rectifier that includes: a second drain electrically connected to the first drain, a second gate, and a second source electrically connected to the first source.

23. A rectifier as recited in claim 22 where the first MESFET rectifier and second MESFET synchronous rectifier are enhancement-mode N-channel devices.

24. A rectifier as recited in claim 22 where the first MESFET rectifier and second MESFET synchronous rectifier are fabricated using gallium arsenide (GaAs) as a semiconductor material.

25. A rectifier as recited in claim 22 where the first MESFET rectifier and second MESFET synchronous rectifier are fabricated using indium phosphide (InP) as a semiconductor material.

26. A rectifier as recited in claim 22 which further comprises a Zener diode with the anode of the Zener diode connected to the first and second sources and the cathode of the Zener connected to the first and second drains.

27. A rectifier as recited in claim 22 which further comprises a Schottky diode with the anode of the Schottky diode connected to the first and second sources and the cathode of the Schottky connected to the first and second drains.

28. A rectifier as recited in claim 26 where the Zener diode is fabricated using silicon as a semiconductor material.

29. A rectifier as recited in claim 26 where the majority of off-state avalanche current flows through the Zener diode.

30. A rectifier as recited in claim 26 where the breakdown voltage of the Zener diode is substantially less than the avalanche breakdown voltage of the first MESFET rectifier and second MESFET synchronous rectifier.

31. A rectifier as recited in claim 26 where a majority of forward bias current is conducted through the combination of the first MESFET rectifier and second MESFET synchronous rectifier and not through the forward bias of the Zener diode.

32. A rectifier as recited in claim 26 which further comprises a Schottky diode with the anode of the Schottky diode connected to the first and second sources and the cathode of the Schottky connected to the first and second drains where the majority of forward bias current is conducted through the parallel combination of the Schottky diode and the first MESFET rectifier and second MESFET synchronous rectifier and not through the forward bias of the Zener diode.

33. A rectifier as recited in claim 27 where the Schottky diode is fabricated monolithically with the first MESFET rectifier and second MESFET synchronous rectifier.

34. A rectifier as recited in claim 21 where the majority of forward bias current is conducted through the second MESFET synchronous rectifier and not through any other device when the second MESFET synchronous rectifier is biased “on”.

35. A rectifier as recited in claim 21 that further comprises a metallization layer that electrically connects the first gate to the first source.

36. A rectifier as recited in claim 21 that further comprises a metallization layer that electrically connects the first source to the second source and the first drain to the second drain.

37. A DC/DC switching power supply that comprises:
a synchronous rectifier MESFET; and
a gate drive circuit, the gate drive circuit configured to prevent activation of the synchronous rectifier MESFET for periods of time that are shorter than a predetermined duration.

38. A DC/DC switching power supply as recited in claim 37 in which the predetermined duration is based on a break-before-make time associated with the converter.

39. A DC/DC switching power supply that comprises:
a synchronous rectifier MESFET;
a pulse width modulation control circuit configured to generate a control signal; and
a gate drive circuit, the gate drive circuit configured to activate the synchronous rectifier MESFET if the control signal remains low for a predetermined duration following transition of the control signal to a logical low state.

40. A DC/DC switching power supply that comprises:
a main switch;
synchronous rectifier MESFET;
a gate drive circuit, the gate drive circuit configured to activate the synchronous rectifier MESFET during a cycle n if the main switch remained in an “off” state for a time that exceeds a predetermined period during the previous cycle n−1.

41. A DC/DC switching power supply as recited in claim 37 where the “off” time of the main switch during the previous cycle n−1 is measured using a timer and compared to the break before make interval of the switching power supply.
